(19) United States
(12) Patent Application Publication
(10) Pub. No.: US 2014/0126164 A1
(43) Pub. Date: May 8, 2014

(54) STARTUP APPARATUS FOR POWER SUPPLY

(71) Applicant: HON HAI PRECISION INDUSTRY CO., LTD., New Taipei (TW)

(72) Inventors: SHIH-FENG LU, New Taipei (TW); CHIA-JUNG LIU, New Taipei (TW); SHU-MING LIU, New Taipei (TW)

(21) Appl. No.: 13/930,172

(22) Filed: Jun. 28, 2013

(30) Foreign Application Priority Data
Nov. 5, 2012 (TW) 101140926

(51) Int. Cl. H05K 5/02

(52) U.S. Cl. CPC H05K 5/0217
USPC 361/752

(57) ABSTRACT

A startup apparatus for a power supply includes an enclosure base, an enclosure cover slidably and pivotably mounted on the enclosure base, a trigger member slidably mounted in the enclosure base, and a power supply switch installed in the enclosure base. The enclosure cover is pushed forward relative to the enclosure base to trigger the trigger member to cause the power supply switch to output power-on instructions to a circuit board in the enclosure base. The enclosure cover is pushed backward relative to the enclosure base to trigger the trigger member to cause the power supply switch to output power-off instructions to the circuit board.

### BACKGROUND

1. Technical Field

The present disclosure relates to a startup apparatus for a power supply.

2. Description of Related Art

Electronic devices such as notebook computers usually include an enclosure base and an enclosure cover pivotably mounted on the enclosure base. A power-on button is positioned on the enclosure base to start up the notebook. Users need to press the power-on button manually to start up the notebook. Such a startup process may be is laborious and the power-on button may be pressed in error.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a startup apparatus for a power supply.

FIG. 2 is an enlarged view of a circled portion II of FIG. 1.

FIG. 3 is an assembled view of the startup apparatus of FIG. 2.

FIG. 4 is an assembled view of the startup apparatus of FIG. 1.

FIG. 5 is an isometric view of the startup apparatus of FIG. 4 with the power supply turned on.

FIG. 6 is an enlarged view of a circled portion VI of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

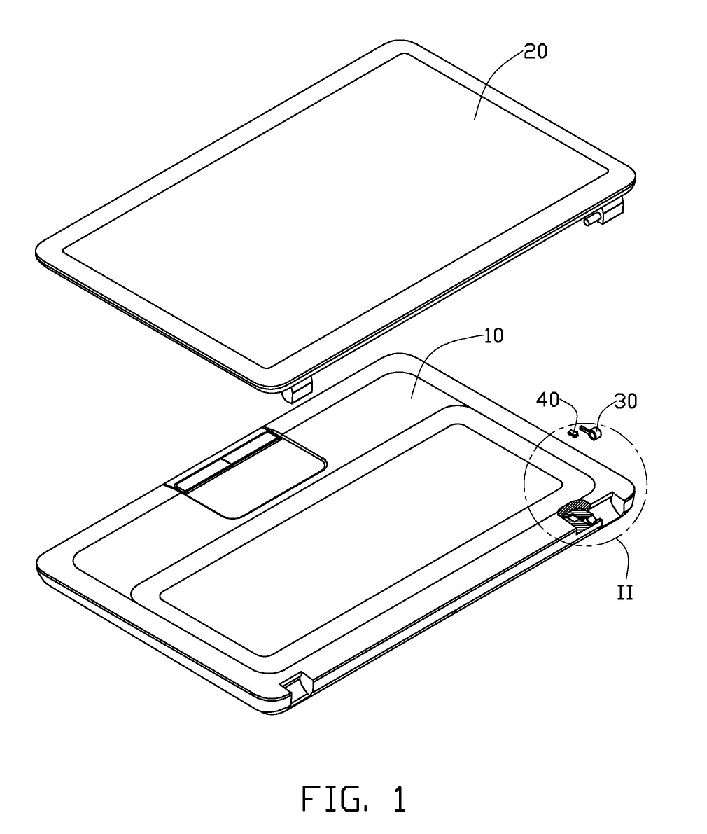

FIG. 1 shows a startup apparatus for a power supply. It includes an enclosure base 10, an enclosure cover 20 pivotably mounted on the enclosure base 10, a trigger member 30 slidably mounted to the enclosure base 10 and the enclosure cover 20, and a power supply switch 40 installed in the enclosure base 10. In one embodiment, the enclosure base 10 and the enclosure cover 20 constitute portable equipment such as a notebook computer.

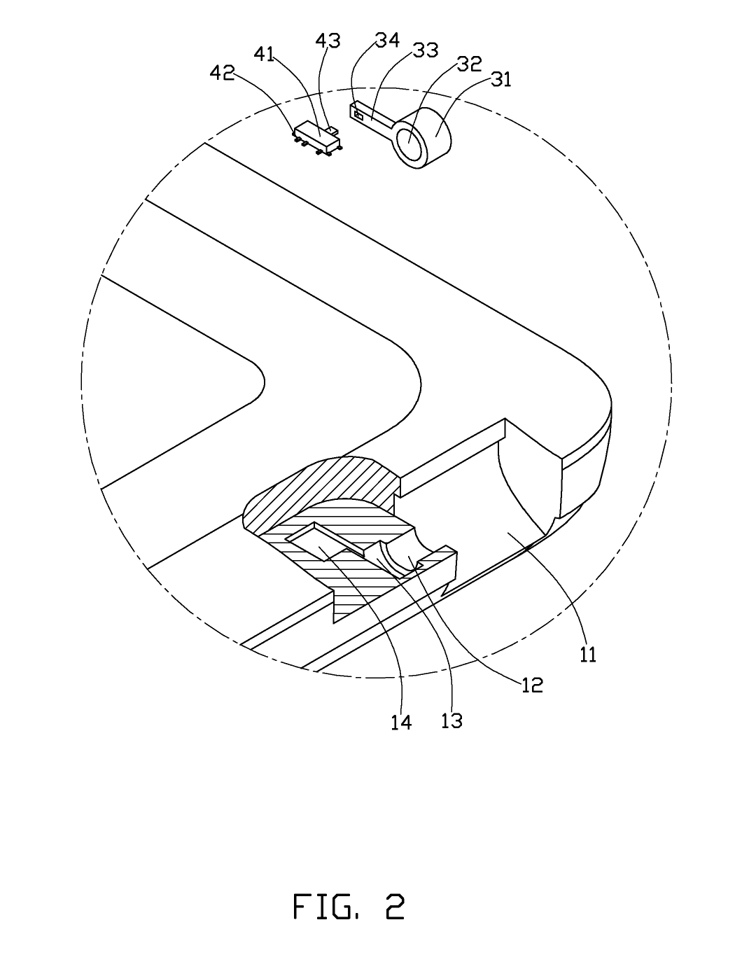

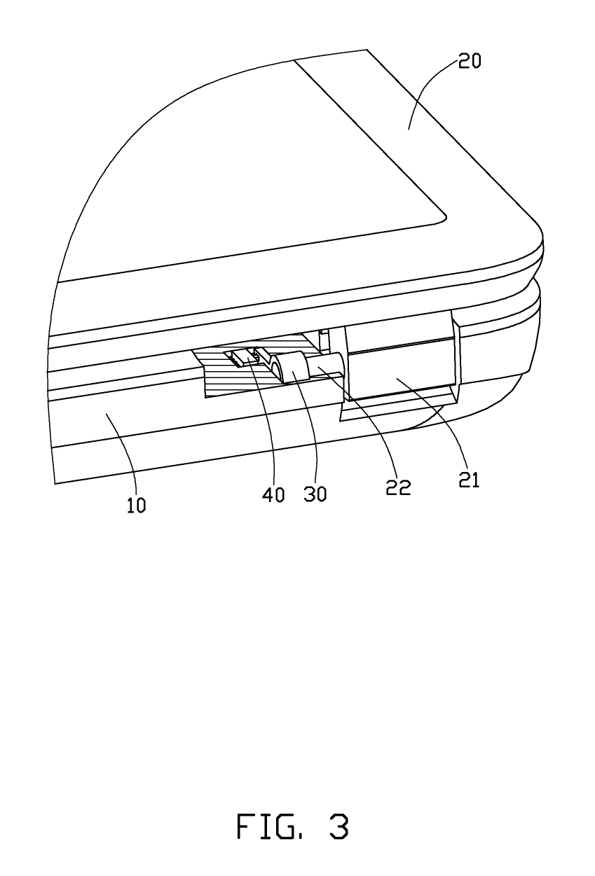

FIGS. 2 and 3 show a cutout 11 and a first groove 12 defined in the enclosure base 10. The cutout 11 and the first groove 12 communicate with each other. A second groove 13 and a third groove 14 are defined in the enclosure base 10 on one side of the first groove 12. The second groove 13 and the third groove 14 communicate with each other. The trigger member 30 is received in the second groove 13. The power supply switch 40 is received in the third groove 14. A pivoting portion 21 protrudes from the enclosure cover 20. A cylindrically-shaped pivoting axle 22 extends from the pivoting portion 21. The pivoting portion 21 is received in the cutout 11. The pivoting axle 22 is received in the first groove 12. In one embodiment, a width of the first groove 12 is greater than a diameter of the pivoting axle 22. A width of the second groove 13 is greater than a width of the trigger member 30. A shape of the third groove 14 corresponds to a shape of the power supply switch 40. A width of the pivoting portion 21 is equal to a width of the cutout 11.

The trigger member 30 includes a ring-shaped engaging portion 31. A circular pivoting hole 32 is defined in the engaging portion 31. The pivoting axle 22 extends through the pivoting hole 32. A bar-shaped connecting portion 33 extends from one side of the engaging portion 31. An accommodating slot 34 is defined in the connecting portion 33. A diameter of the pivoting axle 22 is equal to a diameter of the pivoting hole 32.

The power supply switch 40 includes a cuboid body 41. A plurality of pins 42 extend from a bottom of the body 41. The pins 42 are electrically connected to a circuit board (not shown) on the enclosure base 10. A trigger portion 43 is positioned on one side of the body 41. The trigger portion 43 is received in the accommodating slot 34. In one embodiment, the size of the trigger portion 43 is equal to a size of the accommodating slot 34. When the trigger portion 43 is triggered, the body 41 outputs instructions to the circuit board on the enclosure base 10 via the pins 42, and the circuit board executes the corresponding operations according to the instructions.

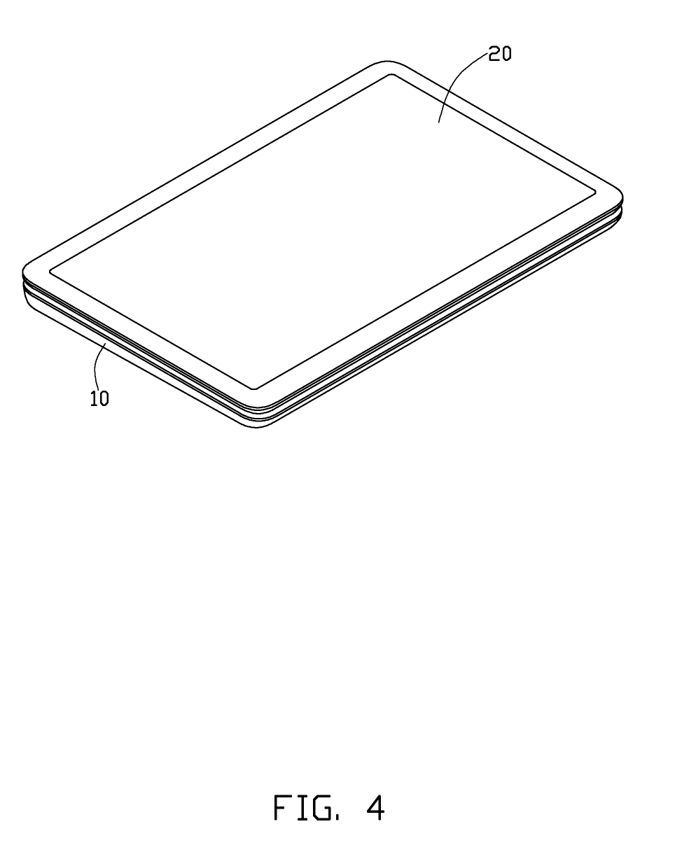

FIGS. 1 to 4 show that in assembly, the trigger member 30 and the power supply switch 40 are located in the enclosure base 10. The engaging portion 31 and the connecting portion 33 are received in the second groove 13. The body 41 is received in the third groove 14, and the trigger portion 43 is received in the accommodating slot 34. The enclosure cover 20 is installed on the enclosure base 10. The pivoting portion 21 is received in the cutout 11. The pivoting axle 22 passes through the pivoting hole 32 and is received in the first groove 12 such that the pivoting portion 21 rotates around the pivoting axle 22.

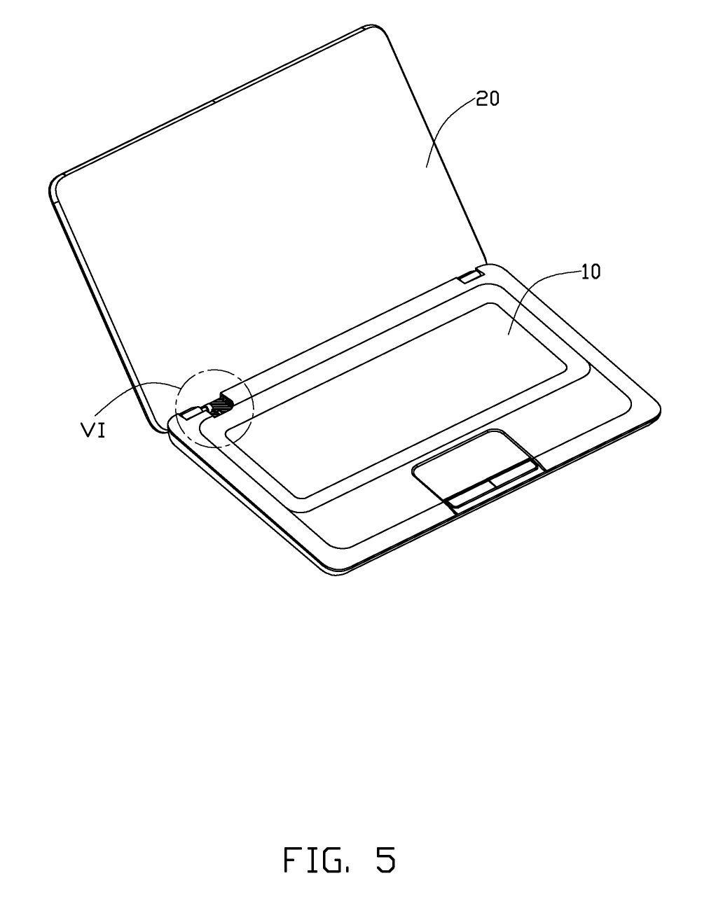

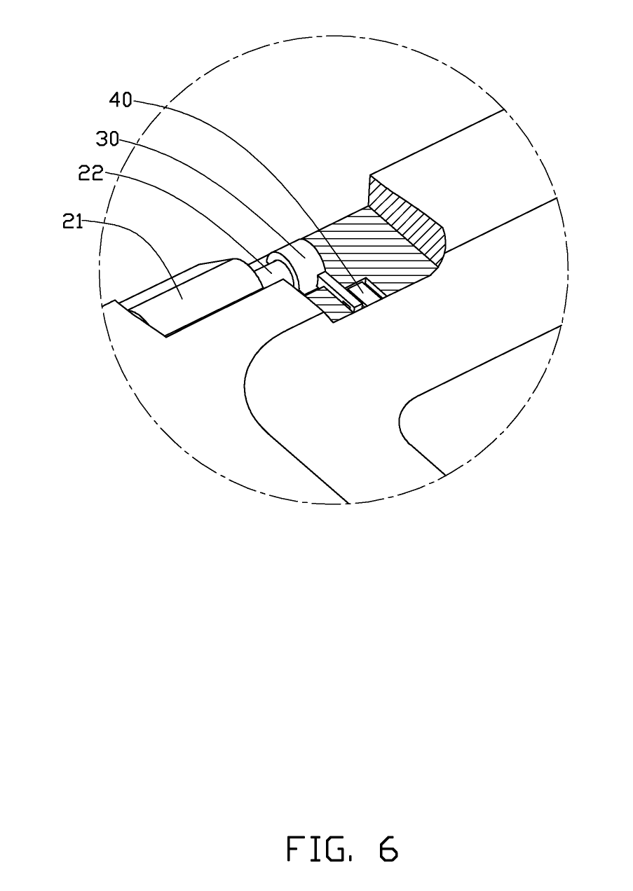

FIGS. 5 and 6 show that in operation, when the circuit board needs to be powered on, the enclosure cover 20 is slid forward relative to the enclosure base 10 in a horizontal direction, causing the trigger member 30 to move forward in the second groove 13. This causes the accommodating slot 34 in the trigger member 30 to move the trigger portion 43 of the power supply switch 40 forward and trigger the trigger portion 43. This causes the body 41 to output power-on instructions to the circuit board in the enclosure base 10 via the pins 42. Then, the enclosure cover 20 is rotated away from the enclosure base 10 via the pivoting portion 21 rotating around the pivoting axle 22.

When the circuit board needs to be powered off, the enclosure cover 20 is rotated toward the enclosure base 10 via the pivoting portion 21 rotating around the pivoting axle 22, and the enclosure cover 20 is slid backward relative to the enclosure base 10 in a horizontal direction, causing the trigger member 30 to move backward in the second groove 13. This causes the accommodating slot 34 in the trigger member 30 to move the trigger portion 43 of the power supply switch 40 backward and trigger the trigger portion 43. This causes the body 41 to output power-off instructions to the circuit board in the enclosure base 10 via the pins 42. In other words, to turn on a device using the present startup apparatus, a user just slides and opens the cover 20. To turn off the device, the user closes and slides the cover 20. Therefore, a less laborious and less error-prone method of turning on and off an electronic device is achieved.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A startup apparatus for power supply comprising:
an enclosure base configured to accommodate a circuit board;
an enclosure cover slidably and pivotably mounted on the enclosure base;
a trigger member slidably mounted to the enclosure base; and
a power supply switch installed in the enclosure base; wherein the enclosure cover is configured to be pushed toward a first direction on the enclosure base, the trigger member moves along the enclosure cover to trigger the power supply switch in a first mode, the power supply switch outputs power-on instructions to the circuit board; and the enclosure cover is configured to be pushed toward a third direction opposite to the first direction on the enclosure base, the trigger member moves along the enclosure cover to trigger the power supply switch in a second mode, the power supply switch outputs power-off instructions to the circuit board.

2. The startup apparatus for power supply of claim 1, wherein the trigger member comprises an accommodating slot; a trigger portion is formed on the power supply switch; the trigger portion is received in the accommodating slot; when the enclosure cover is pushed toward the first direction on the enclosure base, the accommodating slot moves the trigger portion toward the first direction; and when the enclosure cover is pushed toward the third direction on the enclosure base, the accommodating slot moves the trigger portion toward the third direction.

3. The startup apparatus for power supply of claim 2, wherein a size of the trigger portion is equal to a size of the accommodating slot.

4. The startup apparatus for power supply of claim 2, wherein the enclosure base comprises a cutout and a first groove communicated with the cutout; a pivoting portion protrudes from the enclosure cover; a pivoting axle extends from the pivoting portion; the pivoting portion is received in the cutout; and the pivoting axle is received in the first groove.

5. The startup apparatus for power supply of claim 4, wherein the enclosure base further comprises a second groove and a third groove communicated with the second groove; the trigger member is received in the second groove; and the power supply switch is received in the third groove.

6. The startup apparatus for power supply of claim 5, wherein a width of the first groove is greater than a diameter of the pivoting axle; a width of the second groove is greater than a width of the trigger member; a shape of the third groove corresponds to a shape of the power supply switch; and a width of the pivoting portion is equal to a width of the cutout.

7. The startup apparatus for power supply of claim 4, wherein the trigger member comprises an engaging portion; a pivoting hole is defined in the engaging portion; the pivoting axle passes through the pivoting hole and is received in the first groove; a connecting portion extends from one side of the engaging portion; and the accommodating slot is defined in the connecting portion.

8. The startup apparatus for power supply of claim 7, wherein a diameter of the pivoting axle is equal to a diameter of the pivoting hole.

9. The startup apparatus for power supply of claim 7, wherein the power supply switch comprises a body; a plurality of pins extend from a bottom of the body; the plurality of pins are electrically connected to the circuit board; and the trigger portion is positioned on one side of the body.

10. The startup apparatus for power supply of claim 9, wherein the circuit board receives the power-on and the power-off instructions from the body, when the body outputs power-on instructions, the pivoting portion rotates around the pivoting axle and the pivoting hole along a second direction; and when the body outputs power-off instructions, the pivoting portion rotates around the pivoting axle and the pivoting hole along a fourth direction opposite to the second direction.

11. A startup apparatus for power supply comprising:
an enclosure base configured to accommodate a circuit board;
an enclosure cover slidably and pivotably mounted on the enclosure base;
a trigger member slidably mounted to the enclosure base; and
a power supply switch installed in the enclosure base; wherein the circuit board receives a power-on and a power-off instructions from the power supply switch, when the enclosure cover is pushed toward a first direction on the enclosure base, the trigger member moves along the enclosure cover to trigger the power supply switch in a first mode, the power supply switch outputs the power-on instructions to the circuit board, the enclosure cover is rotated away from the enclosure base; and when the enclosure cover is rotated toward the enclosure base, the enclosure cover is pushed toward a third direction opposite to the first direction on the enclosure base, the trigger member moves along the enclosure cover to trigger the power supply switch in a second mode, the power supply switch outputs power-off instructions to the circuit board.

12. The startup apparatus for power supply of claim 11, wherein the trigger member comprises an accommodating slot; a trigger portion is formed on the power supply switch; the trigger portion is received in the accommodating slot; when the enclosure cover is pushed toward the first direction on the enclosure base, the accommodating slot moves the trigger portion toward the first direction; and when the enclosure cover is pushed toward the third direction on the enclosure base, the accommodating slot moves the trigger portion toward the third direction.

13. The startup apparatus for power supply of claim 12, wherein a size of the trigger portion is equal to a size of the accommodating slot.

14. The startup apparatus for power supply of claim 12, wherein the enclosure base comprises a cutout and a first groove communicated with the cutout; a pivoting portion protrudes from the enclosure cover; a pivoting axle extends from the pivoting portion; the pivoting portion is received in the cutout; and the pivoting axle is received in the first groove.

15. The startup apparatus for power supply of claim 14, wherein the enclosure base further comprises a second groove and a third groove communicated with the second groove; the trigger member is received in the second groove; and the power supply switch is received in the third groove.

16. The startup apparatus for power supply of claim 15, wherein a width of the first groove is greater than a diameter of the pivoting axle; a width of the second groove is greater than a width of the trigger member; a shape of the third groove corresponds to a shape of the power supply switch; and a width of the pivoting portion is equal to a width of the cutout.

17. The startup apparatus for power supply of claim 14, wherein the trigger member comprises an engaging portion; a pivoting hole is defined in the engaging portion; the pivoting axle passes through the pivoting hole and is received in the first groove; a connecting portion extends from one side of the engaging portion; and the accommodating slot is defined in the connecting portion.

18. The startup apparatus for power supply of claim 17, wherein a diameter of the pivoting axle is equal to a width of the pivoting hole.

19. The startup apparatus for power supply of claim 17, wherein the power supply switch comprises a body; a plurality of pins extend from a bottom of the body; the plurality of pins are electrically connected to the circuit board; and the trigger portion is positioned on one side of the body.

20. The startup apparatus for power supply of claim 19, wherein the circuit board receives the power-on and the power-off instructions from the body, when the body outputs power-on instructions, the pivoting portion rotates around the pivoting axle and the pivoting hole along a second direction; and when the body outputs power-off instructions, the pivoting portion rotates around the pivoting axle and the pivoting hole along a fourth direction opposite to the second direction.
